(19) United States
(12) Patent Application Publication
(10) Pub. No.: US 2025/0172600 A1
(43) Pub. Date: May 29, 2025

(54) TEST ARRANGEMENT FOR OVER-THE-AIR TESTING AN ANGLED DEVICE UNDER TEST THAT IS TILTED RELATIVE TO A SURFACE OF A CARRIER STRUCTURE

(71) Applicant: Advantest Corporation, Tokyo (JP)

(72) Inventors: José MOREIRA, Stuttgart (DE); Hiromitsu TAKASU, Tokyo (JP); Natsuki SHIOTA, Tokyo (JP); Aritomo KIKUCHI, Tokyo (JP); Yasuyuki KATO, Tokyo (JP); Hiroyuki MINEO, Tokyo (JP)

(21) Appl. No.: 19/038,992

(22) Filed: Jan. 28, 2025

Related U.S. Application Data
(63) Continuation of application No. PCT/EP2023/059654, filed on Apr. 13, 2023.

(30) Foreign Application Priority Data
Jul. 29, 2022 (EP) 22 187 978.6

(51) Int. Cl. G01R 29/10; G01R 31/28; H04B 17/29

(52) U.S. Cl. CPC G01R 29/10; G01R 31/2822; G01R 31/2863; G01R 31/2867; H04B 17/29

(57) ABSTRACT

The invention relates to a test arrangement for over-the-air testing an angled device under test, wherein the test arrangement comprises a carrier structure. The test arrangement comprises a device-under-test socket which is coupled to the carrier structure, wherein the device-under-test socket is configured to establish an electrical contact with an inner surface of the angled device under test or with a connector which is arranged on the inner surface of the angled device under test. The device-under-test socket is configured to position the angled device-under-test such that a first outer surface of the angled device-under-test is tilted by at least 15 degrees with respect to a surface of the carrier structure.

### CROSS-REFERENCES TO RELATED APPLICATIONS

This application is a continuation of copending International Application No. PCT/EP2023/059654, filed Apr. 13, 2023, which is incorporated herein by reference in its entirety, and additionally claims priority from European Application No. EP 22 187 978.6, filed Jul. 29, 2022, which is incorporated herein by reference in its entirety.

Embodiments according to the invention relate to a test arrangement for over-the-air testing, in particular using an angled device under test that is tilted relative to a surface of a carrier structure.

Embodiments according to the invention relate to a socket for over the air testing of L-shaped antenna in Package modules with automated test equipment.

### BACKGROUND OF THE INVENTION

Test arrangements can be used to test devices under test (e.g., an antenna in package device) that are capable of receiving and/or emitting electromagnetic radiation. Commonly a device under test has a flat shape with two opposite surfaces such that, for example, the device under test can be mounted in a device-under-test socket (e.g., an over the air (OTA) socket for radiating near field testing of antenna-in-package devices) such that one of the surfaces faces the device-under-test socket and the other surface faces away from the device-under-test socket. For example, one may orient the device under test such that a surface of the device under test with an antenna faces away from the device-under-test socket.

However, the shape of the device under test may not be planar. For example, the device under test may have an angular shape such as an L-shape. Furthermore, an angled device may be configured to emit and/or receive electromagnetic radiation at at least one outer surface. For example, an angular shaped device under test may have one or more antenna arrays (or other antennas) on one or two outer surfaces.

It has been found that a testing of angled devices under test comprising wireless communication components on one or more outer surfaces typically required high effort for placing the device under test in a device under test socket and that test results are often degraded by artefacts for such devices under test.

Therefore, there is a need for a test arrangement that improves a compromise between testing efficiency, accuracy and reproducibility.

### SUMMARY

An embodiment may have a test arrangement for over-the-air testing an angled device under test, wherein the test arrangement comprises a carrier structure; wherein the test arrangement comprises a device-under-test socket which is coupled to the carrier structure, wherein the device-under-test socket is configured to establish an electrical contact with an inner surface of the angled device under test or with a connector which is arranged on the inner surface of the angled device under test, and wherein the device-under-test socket is configured to position the angled device-under-test-such that a first outer surface of the angled device-under-test is tilted by at least 15 degrees with respect to a surface of the carrier structure.

Another embodiment may have a test arrangement for over-the-air testing an angled device under test, wherein the test arrangement comprises a carrier structure; wherein the test arrangement comprises a device-under-test socket which is coupled to the carrier structure, wherein the device-under-test socket is configured to establish an electrical contact with an inner surface of the angled device under test or with a connector which is arranged on the inner surface of the angled device under test, and wherein the device-under-test socket is configured to position the angled device-under-test—such that a first outer surface of the angled device-under-test is tilted by at least 15 degrees with respect to a surface of the carrier structure, and—such that a second outer surface of the angled device-under-test is tilted by at least 15 degrees with respect to the surface of the carrier structure.

An embodiment of the invention is directed at a test arrangement for over-the-air testing an angled (e.g. L-shaped) device under test (e.g. a L-shape Antenna-in-package device under test, wherein the test arrangement comprises a carrier structure (e.g. a PCB test fixture or a loadboard). The test arrangement comprises a device-under-test socket which is coupled to the carrier structure (e.g. the PCB test fixture or the load board) (e.g. directly or with an extender assembly and/or a PCB interposer in between the carrier structure and the device-under-test socket).

The device-under-test socket is configured to establish an electrical contact with an inner surface of the angled (e.g. L-shaped) device under test (e.g. with an inner surface of the angled device under test which is opposite to a second outer surface of the angled device under test) or with a connector which is arranged on the inner surface of the angled (e.g. L-shaped) device under test. The device-under-test socket is configured to position the angled device-under-test such that a first outer surface of the angled (e.g. L-shaped) device-under-test is tilted by at least 15 degrees with respect to a surface (e.g. a main surface) of the carrier structure (e.g. PCB test fixture or loadboard).

The device-under-test socket allows coupling the angled device under test with the test arrangement. Furthermore, the electrical contact allows transmission (unidirectional or bidirectional) of at least one of electrical power, one or more control signals, a measurement signal, or signals between the test arrangement and the device under test coupled to the device-under-test socket.

At an angle of at least 15° (with respect to the surface of the carrier structure), the first outer surface is no longer approximately parallel to the surface of the carrier structure, which implies that surface normal of the first outer surface is inclined (oblique) with respect to a plane of the carrier structure. Thus, a main lobe direction of an antenna or antenna structure arranged on or in the first outer surface (which is often approximately orthogonal to the first outer surface of the device under test) is typically also inclined with respect to the plane of the carrier structure.

It has been found that this, in turn, helps to reduce a detrimental impact of the carrier structure onto antenna characteristics (e.g. radiation pattern, impedance) of an antenna or antenna structure arranged on or in the first outer surface of the device under test.

Moreover, it has been recognized that by having an inclined first outer surface of the device under test, it typically becomes possible to place a test antenna which transmits a signal to be received at an antenna or antenna structure arranged on or in the first outer surface of the device under test and/or which receives a signal transmitted by an antenna or antenna structure arranged on or in the first outer surface of the device under test offset from a position straight above the device under test (straight above the device under test in a direction perpendicular to the surface of the carrier structure). Accordingly, the test antenna can be placed so as to allow for an efficient insertion of the device under test in a “straight” direction (e.g. along a path with is substantially perpendicular to the surface of the carrier structure). This facilitates the handling of the device under test, since it is, in some cases, not necessary to move the test antenna for insertion of the device under test into the device under test socket and/or for a removal of the device under test form the device under test socket.

Furthermore, it has also been recognized that the inclination of at least 15 degrees of the first outer surface of the angled (e.g. L-shaped) device-under-test (which typically corresponds with a same inclination of a first surface of the device under test socket which abuts a first inner surface of the device under test) allows for (or facilitates) a gravity-supported insertion and/or self alignment of the device under test in the device under test socket. It has been recognized that the inclination of a surface of the device under test socket, which corresponds with the inclination of first outer surface of the device under test. Allows for a smooth, gravity assisted “slipping” of the device under test into the device under test socket.

To conclude, the first outer surface is angled at least partially away from the carrier structure (e.g. inclined with respect to the surface of the carrier structure). As the device under test is angled, a second outer surface arranged past the angle is also angled at least partially away from the carrier structure (e.g. inclined with respect to the surface of the carrier structure). As a result, electromagnetic fields received and/or emitted by either of the outer surfaces (or, more precisely, by a respective antenna or antenna structure arranged on or in the respective outer surface) is at least partially angled away from the carrier structure (e.g. a respective main lobe is inclined with respect to the surface of the carrier structure). As a result, interferences that may be caused by the carrier structure are reduced.

According to an embodiment, the device-under-test socket is configured to position the angled device-under-test such that a second outer surface of the angled (e.g. L-shaped) device-under-test is tilted by at least 15 degrees with respect to the surface (e.g. a main surface) of the carrier structure (e.g. PCB test fixture or loadboard).

Since the device under test is angled and the first and second outer surface are both tilted by at least 15 degrees with respect to the surface of the carrier structure, the angled device under test is arranged in a limited angular range, in which the first and second outer surface are facing away from the carrier structure. Also, typically main lobes of antennas or antenna structures arranged on or in the outer surfaces of the device under test are consequently typically inclined with respect to a surface of the carrier structure, resulting in low interference and allowing for an advantageous placement of respective test antennas for wirelessly testing the device under test. Furthermore, such an orientation brings along an improved probability of self-alignment of the device under test when the device under test is placed into the device-under-test socket. Using such a design of the test arrangement, the first and second outer surfaces are angled such that a path of transmission and/or reception (e.g. a respective main lobe direction of antennas or antenna structures arranged on or in the outer surfaces of the device under test) may not be arranged perpendicular to a surface of the carrier structure. Therefore, structures related to the path of transmission (e.g., antennas, antenna structures, mirrors, or shields) may not be required to be arranged above the device under test (or straight above the device under test), facilitating mounting (inserting) and dismounting (removing) of the device under test.

According to an embodiment, the test socket comprises (at least) two supporting surfaces to support two inner surfaces of the angled device under test, wherein the two supporting surfaces are both tilted by at least 15 degrees with respect to the surface (e.g. a main surface) of the carrier structure (e.g. PCB test fixture or loadboard).

It has been recognized that an angled device under test may have two inner surfaces that may typically be parallel (or close to parallel) to the two outer surfaces. Therefore, an abutment of the inner surfaces of the angled device under test against the two supporting surfaces results in a tilting of the outer surfaces which is at least similar to the tilting of the supporting surfaces. The supporting surfaces may therefore realize an orientation of the first and second outer surface that may be beneficial as discussed herein (e.g., facing at least partially away from a carrier structure that may cause interferences).

According to an embodiment, the test arrangement comprises a support structure which is arranged on a surface of the carrier structure and which comprises a triangular cross-section (e.g. in a plane that is perpendicular to a plane in which the carrier structure lies). The support structure may be configured to carry the device under test socket (e.g. directly or with one or more layers in between). The cross-section may have a shape of a right triangle (i.e. with a 90° angle), wherein the right angle may be arranged at an inner edge of the device under test.

The triangular cross section results in (at least) two supporting surfaces which may abut against the inner surfaces of the angled surfaces of the device under test. The triangular cross section can therefore define the orientation of the outer surfaces of the device under test. Moreover, the usage of a triangular cross section of the support structure allows for the usage of a simple (or conventional) device under test socket. This allows for a cost efficient implementation. In particular, a size of the device under test socket itself can be kept reasonably small, since the tilt is realized by the support structure.

According to an embodiment, the test arrangement comprises a flexible or membrane or elastomeric planar conductor structure (e.g. a flexible or elastomeric printed circuit board) which may be arranged to make a connection between a surface of the carrier structure and a surface of the device under test socket which is tilted with respect to the surface of the carrier structure.

The flexible or membrane or elastomeric planar conductor structure enables establishing an electrical connection between the carrier structure and the device under test socket while being able to adapt to the shape of surfaces of the device-under-test socket. The planar structure reduces changes to the surface structure of the device-under-test socket. For example, the flexible or membrane or elastomeric planar conductor structure allows to adapt the electrical connections to the tilt of the device under test socket or to the tilt of the support structure. For example, the flexible or membrane or elastomeric planar conductor structure may conform with a surface of the support structure, and may, for example, comprise a bent at a transition from the surface of the carrier structure to a surface of the support structure. The usage of such a flexible or membrane or elastomeric planar conductor structure may reduce an implementation effort while providing for a reliable electrical connection.

According to an embodiment, the flexible or membrane or elastomeric planar conductor structure is electrically coupled to a surface of the carrier structure and comprises at least one bent to align with a lower surface of the device under test socket.

The bent allows the flexible or membrane or elastomeric planar conductor structure to adapt to a transition of a surface angle between the carrier structure and the device-under-test socket.

According to an embodiment, the flexible or membrane or elastomeric planar conductor structure extends (at least partly) on a surface of a support structure. The support structure may be arranged on a surface of the carrier structure and may comprise a triangular cross-section (e.g. in a plane that is perpendicular to a plane in which the carrier structure lies). The support structure may be configured to carry the device under test socket (e.g. directly or with one or more layers in between). The flexible or membrane or elastomeric planar conductor structure may be partly arranged between the support structure and the device under test socket.

The flexible or membrane or elastomeric planar conductor structure may adapt to a shape of the triangular cross-section and may enable an electrical contact between the support structure and the device-under-test socket (and optionally the device under test when coupled to the device-under-test socket). The flexible or membrane or elastomeric planar conductor structure may (at least partly) adapt to the shape (or to the surface orientation) of the support structure which may, for example, definee the orientation of the device under test when supporting the device under test socket.

According to an embodiment, the device under test socket comprises one or more coaxial pogo pins (which may, for example, extend from a lower surface of the device under test socket, which is in contact with the PCB test fixture or with the load board or with a support structure or with a flexible or Membrane or elastomeric planar conductor structure, to an upper surface of the device under test socket, which is in contact with the second inner surface of the angled device under test), in order to establish an electrical connection with the angled device under test (wherein, for example, a first end of the coaxial pogo pin may be in contact with a pad on the PCB test fixture or on the load board or on the support structure or on the flexible or Membrane or elastomeric planar conductor structure, and wherein, for example, a second end of the coaxial pogo pin may be in contact with a pad on the angled device under test or with a connector of the angled device under test).

Pogo pins are commonly depressible and allow the device-under-test socket to establish an electrical contact with the device under test upon the device under test being coupled to the device-under-test socket (e.g., when being pushed by a handler/pusher into the device-under-test socket). The coaxial springs enable a high frequency interconnect to the device-under-test socket.

According to an embodiment, the test arrangement comprises a first antenna or antenna structure (e.g. a single aperture antenna (e.g. dual linear polarized or circular polarized)) configured to receive a signal radiated from the first outer surface of the angled device under test and/or configured to emit a signal to be received at the first outer surface of the angled device.

The first antenna or antenna structure allows over-the-air testing a device under test comprising one or more antennas or antenna structures on at least one outer surface. For example, the reception and/or transmission characteristics of one or more antennas or antenna structures on the first outer surface or on the second outer surface of the device under test can be evaluated. However, one or more other characteristics of the device under test can be determined alternatively or in addition. Due to the orientation of the first outer surface of the device under test (e.g. a tilted or inclined or oblique orientation with respect to the surface of the carrier structure) and/or an orientation of the second outer surface of the device under test (e.g. a tilted or inclined or oblique orientation with respect to the surface of the carrier structure), interferences with the carrier structure during (over-the-air) tests are reduced. Furthermore, the orientation may allow the first antenna or antenna structure to not be required to be arranged directly above the device under test, which may facilitate insertion and/or removal of the device under test.

According to an embodiment, the test arrangement comprises a first antenna or antenna structure (e.g. a single aperture antenna (e.g. dual linear polarized or circular polarized)), wherein an aperture of the first antenna or antenna structure is arranged at a distance from the first outer surface of the angled device under test (e.g. with a pusher comprising a low permittivity material or an electromagnetic transparent material in between the first antenna or antenna structure and the first outer surface), such that a surface normal of the first outer surface of the angled device under test extends through the aperture of the first antenna or antenna structure (at least when the second antenna or antenna structure is placed at an operation position).

By arranging the surface normal of the first outer surface through the aperture of the first antenna or antenna structure (which may, for example, be effected by an appropriate alignment of a first surface of the device under test socket, which abuts a first inner surface of the device under test), reception and/or emission of the first antenna or antenna structure may be improved (or, worded differently, a good electromagnetic coupling between an antenna or antenna structure on the first outer surface of the device under test and the first antenna may be achieved). The spacing may facilitate insertion and/or removal of the device under test. The pusher may optionally improve a fixation of the device under test in the device-under-test socket and may also facilitate establishing a reproducible spacing.

According to an embodiment, an antenna aperture of the first antenna or antenna structure is tilted with respect to the carrier structure (e.g. with respect to a surface or main surface of the carrier structure).

The tilt may improve a wireless (electromagnetic) coupling between the antenna aperture and an antenna or antenna structure arranged on or in the first outer surface, which is also tilted. Furthermore, the tilt of the antenna aperture may allow the first antenna or antenna structure to be spaced laterally offset (e.g., parallel to a surface of the carrier structure) from a region straight above a center of the device under test socket, which may facilitate insertion and/or removal of the device under test (e.g. even without moving the first antenna or antenna structure).

According to an embodiment, an antenna aperture of the first antenna or antenna structure is parallel to the first outer surface of the angled device under test.

The parallel arrangement of the antenna aperture and the first outer surface may improve a transmission between the antenna aperture and an antenna or antenna structure arranged on or in the first outer surface.

According to an embodiment, the first antenna or antenna structure is mounted to have a fixed position with respect to the device under test socket.

Such a fixed position allows repeated coupling and testing of a plurality of angled devices under test such that the plurality of angled device under tests have an equal or similar geometrical relationship to the first antenna or antenna structure. As a result, accuracy and reproducibility of the testing may be improved. Moreover, by using a fixed position of the first antenna or antenna structure with respect to the device under test socket, a complexity of the structure can be kept low. Also, by having a fixed positon of the first antenna or antenna structure, a high speed of test can be achieved.

According to an embodiment, the first antenna or antenna structure is mechanically coupled to (e.g. attached to) an arm of a handler (which is configured to insert the angled device under test into the device under test socket, and/or to push the device under test into the device under test socket), such that the first antenna or antenna structure is moveable.

The moveable first antenna or antenna structure may allow easier access to the device-under-test socket (e.g., for insertion and/or removal). Furthermore, the moveable first antenna or antenna structure may allow adjusting the position and/or orientation of the first antenna or antenna structure relative to the tilted first outer surface (e.g., when using sockets with different tilting angles or in order to test angular dependence of the transmission and/or reception of the device under test). Moreover, by making the first antenna or antenna structure moveable, the first antenna or antenna structure can be mechanically coupled with a pusher pushing the device under test into the test socket. Accordingly, the pusher, which may be in between an aperture of the first antenna or antenna structure and the device under test, may accurately adjust a positional relationship between the first outer surface of the device under test and the first antenna or antenna structure.

According to an embodiment, the first antenna or antenna structure is configured to be connected with a signal source and/or with a signal receiver via a blind-mating microwave connection (e.g. via a blind mating (hollow) waveguide connection) when the handler has placed the first antenna or antenna structure in an operating position (or, equivalently, when the handler has inserted the angled device under test into the device under test socket, or when the handler pushes the device under test into the device under test socket).

The signal source enables the first antenna or antenna structure to emit a signal (e.g., to be received by an antenna array of the angled device under test) and/or the signal receiver allows to evaluate a signal received by the first antenna or antenna structure (e.g., emitted by an antenna array of the angled device under test). Thus, the usage of a signal source and/or of a signal receiver facilitates testing of the angled device under test. The blind-mating microwave connection facilitates (e.g., manual and/or automatic) coupling of the signal source with the first antenna or antenna structure and coupling of the signal receiver with the first antenna or antenna structure. The blind-mating microwave connection may also allow removal of at least a portion of the first antenna or antenna structure, which may improve accessibility of the device-under-test socket.

According to an embodiment, the test arrangement comprises a second antenna or antenna structure (e.g. a single aperture antenna (e.g. dual linear polarized or circular polarized)) configured to receive a signal radiated from an antenna or antenna structure arranged on or in the second outer surface of the angled device under test and/or to emit a signal to be received by an antenna or antenna structure arranged on or in the second outer surface of the angled device under test (at least when the second antenna or antenna structure is placed at an operation position) (or, equivalently, when the handler has inserted the angled device under test into the test socket, or when the handler pushes the device under test into the test socket).

The second antenna or antenna structure allows testing an antenna structure on or in the second outer surface, and/or allows for a wireless testing of one or more other components of the device under test. The second antenna or antenna structure benefits from an orientation of the second outer surface defined by the device-under-test socket.

The first and second antenna or antenna structure can test signals emitted and/or received by antennas or antenna structures arranged on or in the first and second outer surface (e.g., simultaneously or successively) without having to recouple (or rearrange) the angled device under test at a different orientation (e.g., or a different device-under-test socket).

For example, both the first antenna or antenna structure and the second antenna or antenna structure can be arranged in such a manner that the first and second antenna or antenna structure do not hinder an insertion of the device under test into the device under test socket and/or a removal of the device under test from the device under test socket.

According to an embodiment, the test arrangement comprises a second antenna or antenna structure (e.g. a single aperture antenna (e.g. dual linear polarized or circular polarized)), wherein an aperture of the second antenna or antenna structure is arranged at a distance from the second outer surface of the angled device under test (e.g. with a pusher comprising a low permittivity material or an electromagnetic transparent material in between the second antenna or antenna structure and the second outer surface), such that a surface normal of the second outer surface of the angled device under test (or, equivalently, a surface normal of a second surface of the device under test socket which abuts a first inner surface of the device under test) extends through the aperture of the second antenna or antenna structure (at least when the second antenna or antenna structure is placed at an operation position) (or, equivalently, when the handler has inserted the angled device under test into the test socket, or when the handler pushes the device under test into the test socket). The second (and/or first) outer surface may have or be configured to emit and/or receive (e.g., by beamforming) a main lobe in a direction perpendicular to the second (and/or first) outer surface.

In other words, one or more antennas or antenna structures may be arranged on or in the first outer surface of the device under test and/or on or in the second outer surface of the device under test, and one or more of these antennas or antenna structures may have main lobe directions substantially perpendicular to a respective outer surface.

By arranging the surface normal of the second outer surface through the aperture of the second antenna or antenna structure, a good reception of a signal emitted by an antenna or antenna structure arranged on or in the second outer surface at the side of the second antenna or antenna structure can be achieved. Alternatively or in addition, a good reception of a signal emitted by the second antenna or antenna structure at the side of the antenna or antenna structure arranged on or in the second surface can also be achieved in this way.

According to an embodiment, an antenna aperture of the second antenna or antenna structure is tilted with respect to the carrier structure (e.g. with respect to a surface or main surface of the carrier structure).

The tilt may improve an electromagnetic coupling between the antenna aperture of the second antenna or antenna structure and an antenna or antenna structure arranged on or in the second outer surface, which is also tilted. Furthermore, the tilt of the antenna aperture of the second antenna or antenna structure may allow the second antenna or antenna structure to be spaced laterally offset (e.g., in a direction parallel to a surface of the carrier structure) with respect to the device under test socket, which may facilitate insertion and/or removal of the device under test.

According to an embodiment, an antenna aperture of the second antenna or antenna structure is parallel to the second outer surface of the angled device under test (or, equivalently, is parallel to a second surface of the device under test socket which abuts a second inner surface of the device under test).

The parallel arrangement of the antenna aperture of the second antenna or antenna structure and the second outer surface may improve an electromagnetic coupling between the antenna aperture and the second outer surface.

According to an embodiment, the second antenna or antenna structure is mounted to have a fixed position with respect to the device under test socket.

Such a fixed position allows repeated coupling and testing of a plurality of angled devices under test such that the plurality of angled device under tests have an equal or similar geometrical relationship to the second antenna or antenna structure. As a result, accuracy and reproducibility of the testing may be improved.

According to an embodiment, the second antenna or antenna structure is mechanically coupled (e.g. attached) to an arm of a handler (which is configured to insert the angled device under test into the device under test socket), such that the second antenna or antenna structure is moveable.

The moveable second antenna or antenna structure may allow easier access to the device-under-test socket (e.g., for insertion and/or removal of the device under test). Furthermore, the moveable second antenna or antenna structure may allow adjusting the position and/or orientation of the second antenna or antenna structure relative to the tilted second outer surface (e.g., when using sockets with different tilting angles or in order to test angular dependence of the transmission and/or reception of the device under test).

According to an embodiment, the first antenna or antenna structure and/or the second antenna or antenna structure is part of a pusher for pushing the angled device under test into the device under test socket. Alternatively, the first antenna or antenna structure and/or the second antenna or antenna structure may be configured to be moveable together with a pusher for pushing the angled device under test into the device under test socket (wherein, for example, the pusher is arranged such that the pusher, or a part of the pusher, is in between the first antenna or antenna structure and the first outer surface of the angled device under test when the device under test in inserted into the device under test socket) (wherein, for example, the pusher is arranged such that the pusher, or a part of the pusher, is in between the second antenna or antenna structure and the second outer surface of the angled device under test when the device under test in inserted into the device under test socket).

Thus, for example, at least a portion of the first and/or second antenna or antenna structure is movable with the pusher and can therefore be moved (e.g., for easier coupling of the angled device under test to the device-under-test socket) or readjusted (e.g., an orientation thereof). For example, if the pusher is configured to push the angled device under test into the device-under-test socket, the pusher may facilitate coupling and positioning the second antenna or antenna structure during coupling of the angled device under test to the device-under-test socket. In case the first and second antenna or antenna structure are movable together with the pusher, the position of these components and therefore testing is more reproducible, since a positional relationship between the first and second antenna or antenna structure and the device under test may be well-defined by the spacer (e.g. if the spacer directly abuts the outer surfaces of the device under test and antenna apertures of the first and second antenna or antenna structure).

According to an embodiment, the second antenna or antenna structure is configured to be connected with a signal source and/or with a signal receiver via a blind-mating microwave connection (e.g. via a blind mating waveguide connection) when the handler has placed the second antenna or antenna structure in an operating position (or, equivalently, when the handler has inserted the angled device under test into the test socket, or when the handler pushes the device under test into the test socket).

The signal source enables the second antenna or antenna structure to emit a signal (e.g., to be received by an antenna array of the angled device under test) and/or the signal receiver allows to evaluate a signal received by the second antenna or antenna structure (e.g., emitted by an antenna array of the angled device under test). Thus, the usage of a signal source and/or of a signal receiver facilitates testing of the angled device under test. The blind-mating microwave connection facilitates (e.g., manual and/or automatic) coupling of the signal source with the first antenna or antenna structure and/or coupling of the signal receiver with the second antenna or antenna structure. The blind-mating microwave connection may also allow removal of at least a portion of the second antenna or antenna structure, which may improve accessibility of the device-under-test socket.

According to an embodiment, the test arrangement comprises a pusher for pushing the angled device under test into the test socket. The pusher may be configured such that a first pushing surface is parallel to the first outer surface of the angled device under test when the pusher is in a pushing position such that a second pushing surface is parallel to the second outer surface of the angled device under test when the pusher is in the pushing position.

The first and second pushing surfaces can therefore simultaneously abut (and push) against the first and second outer surfaces (e.g. in case that the pusher is pressed towards the carrier structure). Therefore, the pusher may exert a relatively homogenously distributed force onto the device under test. Furthermore, the first and second pushing surfaces may fix a position and orientation of the device under test in a reliable manner.

According to an embodiment, the test arrangement comprises a pusher for pushing the angled device under test into the test socket, wherein the pusher is configured such that a first pushing surface of the pusher is tilted with respect to the carrier structure (e.g. with respect to a surface or main surface of the carrier structure) when the pusher is in the pushing position (for pushing the angled device under test into the device under test socket), and wherein the pusher is configured such that a second pushing surface of the pusher is tilted with respect to the carrier structure (e.g. with respect to a surface or main surface of the carrier structure) when the pusher is in the pushing position.

The tilted angles of the first and second pushing surfaces improve alignment of the device under test when the pusher abuts against the one or more tilted surfaces of the device under test when the device under test is moving into the device under test socket or when the device under test is located inside the device-under-test socket.

According to an embodiment, the device under test socket comprises an angled recess or an angled exemption, configured to support and/or align the angled device under test. The angled recess may have a border that surrounds at least a part of the angled recess or angled exemption.

The angled recess or angled exemption may improve alignment of the device under test in the device-under-test socket. The alignment may at least partially be guided by the border of the angled recess. The border may, for example be configured to support the pusher (e.g., in order to reduce excess forces onto the device under test). For example, the angled recess may be configured to support a self-alignment of the device under test, e.g. by having somewhat tilted side surfaces.

According to an embodiment, the device under test socket is arranged such that a second inner surface of the angled device under test, which is opposite to the second outer surface of the angled device under test (and/or a first inner surface of the angled device under test, which is opposite to the second outer surface of the angled device under test, or to the first outer surface of the device under test), is spaced from the carrier structure (e.g. loadboard) by at least 10 mm, or by at least 30 mm, or by at least 45 mm or by at least 2 wavelengths or by at least 3 wavelengths or by at least by 4 wavelengths (e.g. free-space wavelengths, or wavelengths in a medium between the first outer surface of the angled device under test and the carrier structure) at a lowest frequency of operation of the angled device under test (e.g. at a lowest frequency of operation of an Antenna-in-Package (AiP) module that makes up the device under test or that is included in the device under test) (and such that, advantageously, an edge of the first outer surface is spaced from the loadboard by at least 10 mm, or by at least 20 mm or by at least 2 wavelengths or by at least 3 wavelengths or by at least by 4 wavelengths, e.g. free-space wavelengths, or wavelengths in a medium between the first outer surface of the angled device under test and the carrier structure, at a lowest frequency of operation of the angled device under test, e.g. at a lowest frequency of operation of an Antenna-in-Package (AiP) module that makes up the device under test or that is included in the device under test).

It has been recognized that the spacing of the inner surfaces of the device under test further reduces interferences in electromagnetic radiation emitted by or received at the device under test and caused by the carrier structure.

According to an embodiment, the device under test socket comprises a maximum socket height (e.g. a height where an inner edge of the angled device under test is located when the angled device under test is placed in the device under test socket) of at least 10 mm, or of at least 30 mm, or of at least 45 mm, or of at least 2wavelengths or of at least 3 wavelengths or of at least by 4 wavelengths (e.g. free-space wavelengths, or wavelengths in a medium between the first outer surface of the angled device under test and the carrier structure) at a lowest frequency of operation of the angled device under test (e.g. at a lowest frequency of operation of an Antenna-in-Package (AiP) module that makes up the device under test or that is included in the device under test).

It has been recognized that such a geometry of the device-under test socket, which results in a distance between the device under test and the carrier structure, results in sufficiently small interferences with respect to electromagnetic radiation emitted by or received at the device under test and caused by the carrier structure.

According to an embodiment, the first antenna or antenna structure and the second antenna or antenna structure are arranged such that the angled device under test can be inserted into the device under test socket in a direction which is perpendicular to a surface (e.g. a main surface) of the carrier structure without moving the first antenna and the second antenna. Alternatively or additionally, the first antenna or antenna structure and the second antenna or antenna structure may be arranged such that the angled device under test can be removed from the device under test socket in a direction which is perpendicular to a surface (e.g. a main surface) of the carrier structure without moving the first antenna and the second antenna.

Insertion and/or removal of the device under test without moving the first and second antenna structure improves testing efficiency and reliability for testing one or more devices under test. Implementation of such an arrangement may be facilitated by at least the first outer surface of the device under test being tilted. Therefore, at least the first antenna or antenna structure may be laterally offset due to a tilted path for transmission of electromagnetic signals (between the first antenna or antenna structure and the first outer surface of the device under test).

According to an embodiment, a spacing between the first antenna or antenna structure and the second antenna or antenna structure is chosen such that the angled device under test can be straightly (e.g. in a straight line) moved through the spacing in a direction which is perpendicular to a surface (e.g. a main surface) of the carrier structure. Thus, insertion and

Removal of the device under test can be effected in a very efficient and rapid manner.

According to an embodiment, a test arrangement for over-the-air testing an angled (e.g. L-shaped) device under test (e.g. a L-shape Antenna-in-package device under test) is provided. The test arrangement comprises a carrier structure (e.g. a PCB test fixture or a loadboard) and a device-under-test socket which is coupled to the carrier structure (e.g. the PCB test fixture or the load board) (e.g. directly or with an extender assembly and/or a PCB interposer in between the carrier structure and the device-under-test socket). The device-under-test socket is configured to establish an electrical contact with an inner surface of the angled (e.g. L-shaped) device under test (e.g. with an inner surface of the angled device under test which is opposite to a second outer surface of the angled device under test) or with a connector which is arranged on the inner surface of the angled (e.g. L-shaped) device under test. The device-under-test socket is configured to position the angled device-under-test such that a first outer surface of the angled (e.g. L-shaped) device-under-test is tilted by at least 15 degrees with respect to a surface (e.g. a main surface) of the carrier structure (e.g. PCB test fixture or loadboard). The device-under-test socket is configured to position the angled device-under-test such that a second outer surface of the angled (e.g. L-shaped) device-under-test is tilted by at least 15 degrees with respect to the surface (e.g. a main surface) of the carrier structure (e.g. PCB test fixture or loadboard). This test arrangement comprises similar advantages like the above discussed test arrangements. The test arrangement may optionally be supplemented by any of the features, functionalities and details disclosed herein, both individually and taken in combination.

### BRIEF DESCRIPTION OF THE DRAWINGS

Embodiments of the present invention will be detailed subsequently referring to the appended drawings, in which:

FIG. 1 shows a schematic cross-section of an example of a test arrangement for over-the-air testing an angled device under test;

FIG. 2A shows a schematic cross section through a first example of an angled device under test;

FIG. 2B shows a schematic cross section through a second example of an angled device under test;

FIG. 3 shows a perspective view of an angled device under test;

FIG. 4 shows a result of a simulation of a far field emitted by an antenna element of a first outer surface antenna array of the device under test depicted in FIG. 3;

FIG. 5 shows a perspective view of an angled device under test;

FIG. 6 shows a result of a simulation of a far field emitted by one antenna element of a first outer surface antenna array of the device under test depicted in FIG. 5;

FIG. 7A shows a perspective view of an example of a device under test;

FIG. 7B shows a different perspective view of the device under test depicted in FIG. 7A;

FIG. 8 shows a schematic cross section of an example of a test arrangement for over-the-air testing an angled device under test; and

FIG. 9 shows a perspective view of an example of a device-under-test socket.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may optionally be combined with each other, unless specifically noted otherwise.

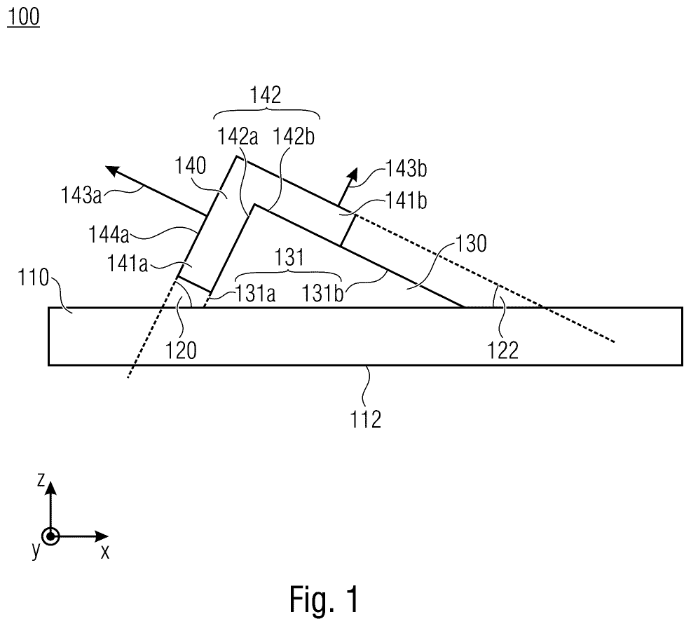

FIG. 1 shows a schematic cross-section of an example of a test arrangement 100 for over-the-air testing an angled device under test 140.

The test arrangement 100 comprises a carrier structure 110 and a device-under-test socket 130 which is coupled to the carrier structure 110. The device-under-test socket 130 is configured to establish an electrical contact with an inner surface 142 of the angled device under test 140 or with a connector (not shown in FIG. 1) which is arranged on the inner surface 140 of the angled device under test 140. The device-under-test socket 130 is configured to position the angled device-under-test 140 such that a first outer surface of the angled device-under-test is tilted by a first angle 120 of at least fifteen degrees with respect to a surface 112 of the carrier structure 110.

The carrier structure 110 may be (or comprise) a printed circuit board (PCB) test fixture or a loadboard. The carrier structure 110 may, for example, comprise regions with a flat surface. The device-under-test-socket 130 may be arranged on top of the carrier structure 110 (e.g., on the flat surface) or may be coupled to the carrier structure 110 via one or more intermediate devices.

The test arrangement 100 shown in FIG. 1 can, for example, be used to test the angled device under test 140 itself (e.g., without antenna structures detecting electromagnetic radiation emitted by the angled device under test) or to test the angled device under test 140 in combination with one or more additional antennas. For example, the test arrangement 100 may be used to test a power consumption of the device under test 140 or interferences between antennas of the device under test 140). Alternatively, the test arrangement 100 may be configured to wirelessly test one or more antenna structures of the device under test.

Since the device-under-test socket 130 is configured to contact an inner surface 142 of the device under test, outer surfaces of the device under test 140 completely (or at least mostly) face away from the device-under-test socket 130 and the carrier 110. Therefore, an effect of the device-under-test socket 130 and/or the carrier structure 110 on a radiation emitted (and/or received) by the outer surfaces of the device under test 140 (and on a testing thereof) is reduced. Furthermore, the first angle 120 of at least fifteen degrees allows the first outer surface 144a and a second outer surface 144b to face away from the carrier structure 110. Therefore, the first and second outer surfaces 144a, b have improved accessibility from the top, e.g., for mounting, attachment, and transmission and/or reception. The tilted angle facilitates alignment with surfaces of the device-under-test socket 130 when a force perpendicular to the surface of the carrier structure 110 (e.g. gravitational force) is applied to the device under test 140.

The angled device under test 140 may be (or comprise) an Antenna-in-package (AiP) device. The angled device under test 140 may have an L-shape (as indicated abstractly in FIG. 1), e.g., the device under test may be a device with a first plate 141a connected to a second plate 141b, wherein the plates 141a, 141b are angled relative to each other at at least essentially 90 degrees (e.g., within a tolerance of +/−15 degrees). The angled device under test 140 may comprise a first outer surface 144a (e.g., of the first plate 141a) and a second outer surface 144b (e.g., of the second plate 141b), wherein the first and second outer surfaces 144a, b are angled relative to each other at at least essentially 270 degrees (e.g., within a tolerance of +/−15 degrees). The inner surface 142 of the angled device under test 140 may comprise a first inner surface 142a (e.g., of the first plate 141a) and a second inner surface 142b (e.g., of the second plate 141b), wherein the first and second inner surfaces 142a, b are angled relative to each other at at least essentially 90 degrees (e.g., within a tolerance of +/−15 degrees). The first inner surface 142a and the first outer surface 144a may be arranged parallel to each other. The second inner surface 142b and the second outer surface 144b may be arranged parallel to each other.

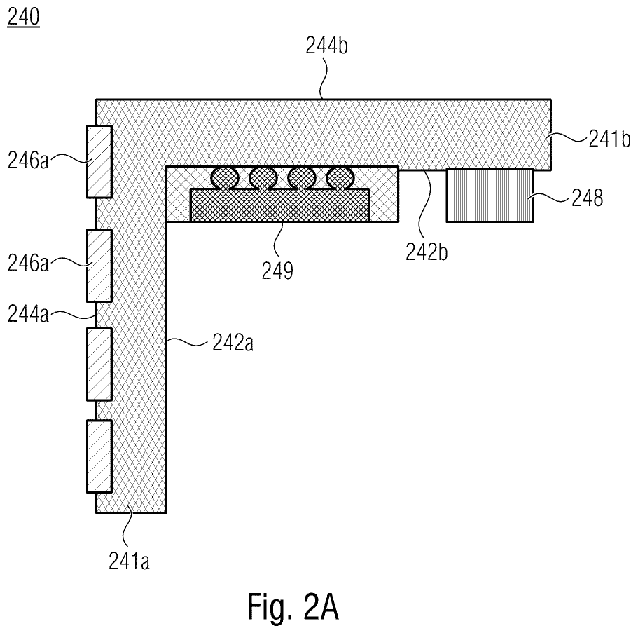

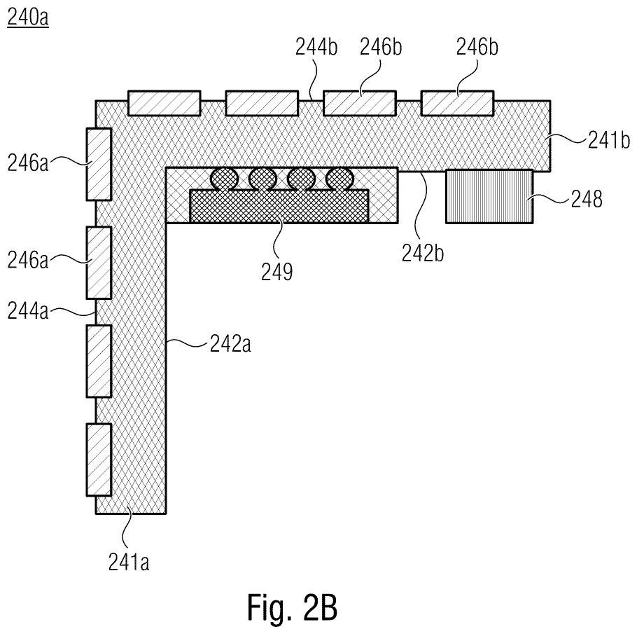

FIG. 2A shows a schematic cross section through a first example of an angled device under test 240, which can take the place of the angled device under test 140.

The device under test 240 comprises a first plate 241a and a second plate 241b, which are angled relative to each other at a 90 degree angle (e.g., within a tolerance of +/−15 degrees). The first plate 241a comprises a first outer surface 244a and a first inner surface 242a and the second plate 241b comprises a second outer surface 244b and a second inner surface 242b.

In the example shown in FIG. 2A the first outer surface 244a comprises a first antenna array 246a with four antenna elements. However, the first outer surface 244a may (additionally or alternatively) comprise any other form of antenna (e.g., a single antenna and/or a circular polarized antenna) and any other number of antenna elements or antenna arrays. Alternatively, the second outer surface 244b may comprise the first antenna array 246a. The first antenna array 246a may be configured to receive and/or transmit electromagnetic radiation.

The device under test 240 may further comprise a connector 248, e.g., an array connector. In the example shown in FIG. 2A, an (array) connector 248 is arranged on the second inner surface 242b. Alternatively, the (array) connector 248 may be arranged on the first inner surface 242a or (e.g., in the case of a plurality of (array) connectors 248) on the first and second inner surface 242a, b. The (array) connector 248 is electrically connected with at least one antenna element (e.g., all of the antenna elements) of the first antenna array 246a. Therefore, an electrical signal applied at the (array) connector 248 may cause the first antenna array 246a to emit electromagnetic radiation. Alternatively or additionally, electromagnetic radiation received by the first antenna array 246a may result in an electric signal at the (array) connector 248. The (array) connector 248 may be or comprise one or more solder balls. The (array) connector 248 may be configured to connect the device under test 140 (e.g., an antenna in package module) to a system (e.g. a cell phone or the device-under-test socket 130) and may enable transmission of signals like a power signal, a digital signal, radio frequency (RF) signal or an intermediate frequency (IF) signal.

The first antenna array 246a may be electrically connected directly with the (array) connector 248 or may be indirectly coupled with the (array) connector 248, e.g., with further electrical components in between. For example, the further electrical components may comprise at least one of an amplifier, a filter, a switch, a resistor, a capacitor, and an integrated circuit. In the example shown in FIG. 2A, the further electrical components comprise an antenna circuitry 249 (e.g., a silicon die). The antenna circuitry 249 may be configured to convert intermediate frequency (IF) signals into mmWave signals (e.g., of a 5G bandwidth such as in a range of 24 GHZ to 53 GHz) and/or vice versa. Alternatively or additionally, the antenna circuitry 249 may be configured to control (at least partly) beamforming of the first antenna array 246a.

FIG. 2B shows a schematic cross section through a second example of an angled device under test 240a, which can take the place of the angled device under test 140. The second example of the angled device under test 240a essentially corresponds to the first example of the angled device under test 240 as shown in FIG. 2A, such that identical elements will be designated with identical reference numerals, but further comprises a second antenna array 246b on the second outer surface 244b. The second antenna array 246b may have similar (or the same) features as the first antenna array 246a. The second antenna array 246b may also be electrically connected to at least one of the (array) connector 248 and the antenna circuitry 249. Alternatively, the second antenna array 246b may be electrically connected to a separate (array) connector and/or to a separate antenna circuitry.

The device-under-test socket 130 may be configured to position the angled device-under-test 140 (e.g. the angled device under test 240 or the angled device under test 240a) such that the first outer surface 144a of the angled device under test 140 (e.g., the first outer surface 244a) is spaced apart and/or facing away from the surface 112 of the carrier structure 110. The device-under-test socket 130 may be configured to position the angled device-under-test 140 such that that a surface normal 143a of the first outer surface 144a of the angled device-under-test 140 is tilted by an angle of at least fifteen degrees with respect to a surface normal of the surface 112 of the carrier structure 110. The device-under-test socket 130 may be configured to position the angled device-under-test 140 such that that a surface normal 143b of the second outer surface 144b of the angled device-under-test 140 is tilted by an angle of at least fifteen degrees with respect to a surface normal of the surface 112 of the carrier structure 110.

The device-under-test socket 130 may be arranged such that, advantageously, an edge of the first and/or second outer surface 144a, b is spaced from the carrier structure 110 by at least 10 mm, or by at least 20 mm or by at least 2 wavelengths or by at least 3 wave-lengths or by at least by 4 wavelengths, e.g. free-space wavelengths, or wavelengths in a medium between the first and/or second outer surface 844a, b of the angled device under test 840 and the carrier structure 810, at a lowest frequency of operation of the angled device under test, e.g. at a lowest frequency of operation of an Antenna-in-Package (AiP) module that makes up the de-vice under test or that is included in the device under test. The angled device under test 140 may be operated in a frequency band of the 5G standard, for example a bandwidth with the range of 24 GHz to 53 GHz (e.g., the 5G frequency range 2). In such a case, the lowest frequency of operation may be 24 GHz with a wavelength of 12.5 mm. The space between the edge of the first and/or second outer surface 144a, b and the surface 112 of the carrier structure 110 may be 25 mm or larger (i.e. two times 12.5 mm).

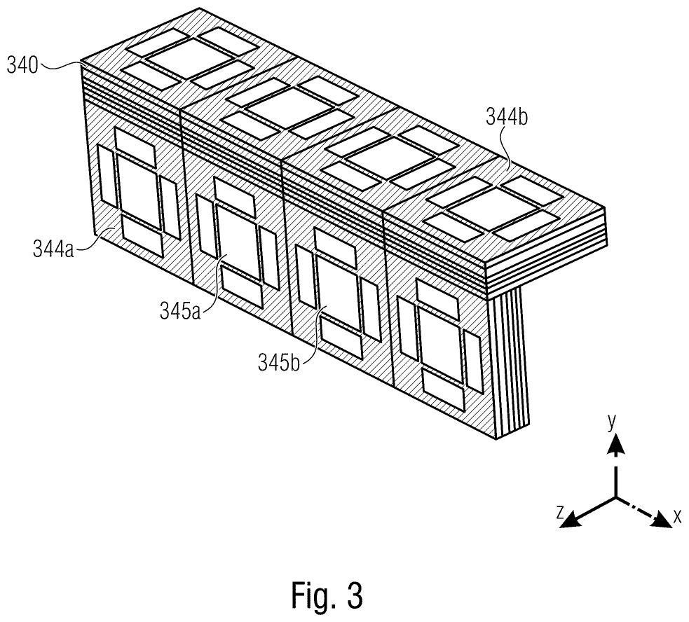

FIG. 3 shows a perspective view of an angled device under test 340, which can take the place of the angled device under test 140.

The device under test 340 comprises a first outer surface 344a with a first antenna array having four antenna elements and a second outer surface 344b with a second antenna array having four antenna elements. At least one antenna element may comprise at least one parasitic patch. In the example shown in FIG. 3, each antenna element comprises four parasitic patches. The first outer surface 344 a comprises two central antenna elements 345a, b. There is not metalized surface in the vicinity of the device under test 340, which can take the place of the angled device under test 140.

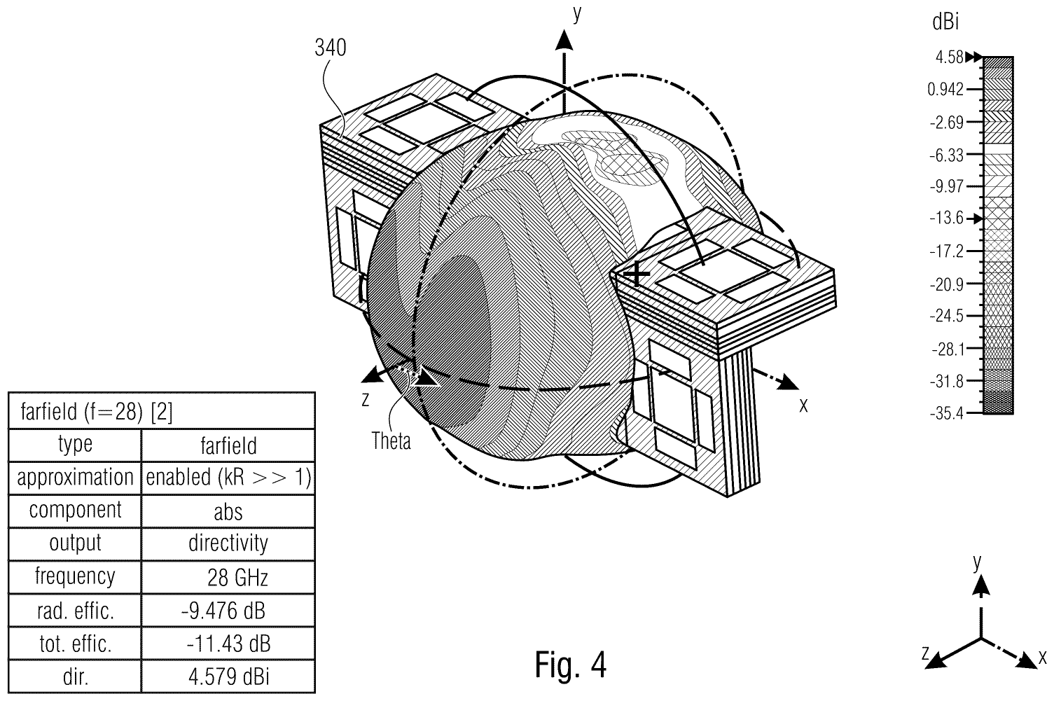

FIG. 4 shows a result of a simulation of a far field emitted by an antenna element (e.g., one of the central antenna elements 345a, b) of the first outer surface 344a of the device under test 340 depicted in FIG. 3. The far field shows pronounced lobes oriented perpendicular to the two central antenna elements 345a, b of the first outer surface 344a (wherein, however, a radiation in a backward direction may be reduced or suppressed when the device under test 340 is applied in a system, e.g., in a system providing a metallized backplane).

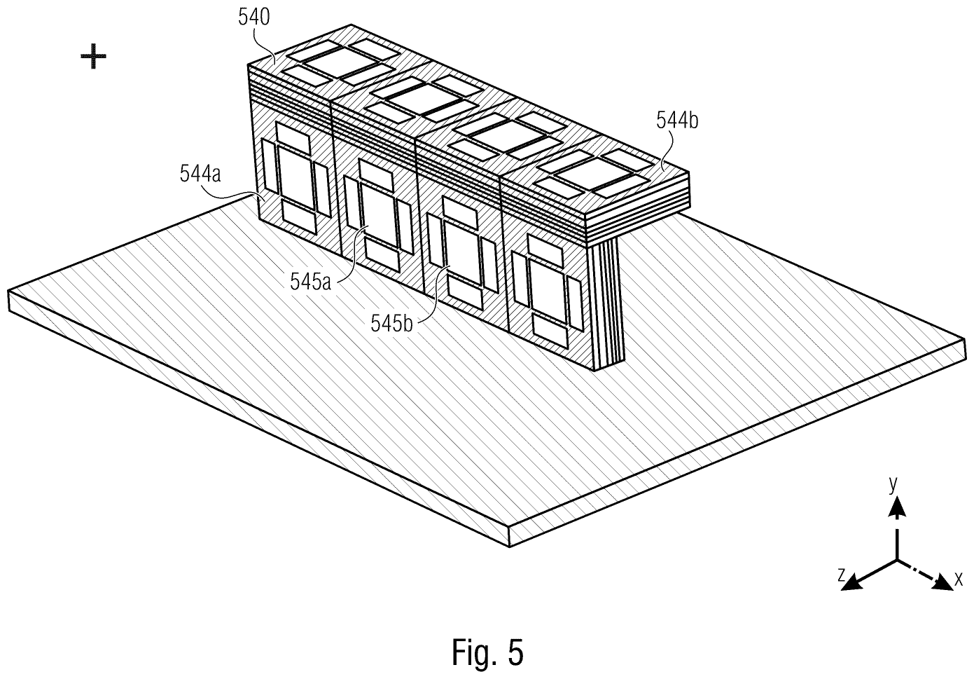

FIG. 5 shows a perspective view of an angled device under test 540, which can take the place of the angled device under test 140. The device under test 540 comprises a first outer surface 544a with a first antenna array having four antenna elements and a second outer surface 544b with a second antenna array having four antenna elements. The first outer surface 544 a comprises two central antenna elements 545a, b. There is metal (e.g., copper) surface 550 in a distance of 2 mm away from the first outer surface 544a.

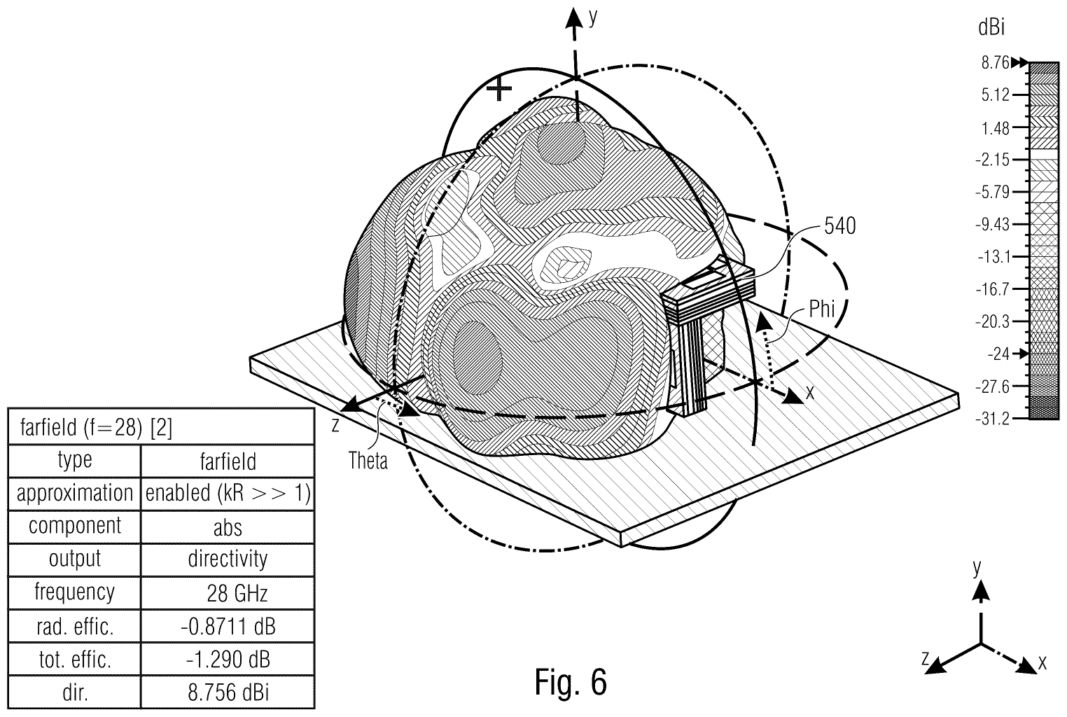

FIG. 6 shows a result of a simulation of a far field emitted by an antenna element (e.g., one of the central antenna elements 545a, b) of the first antenna array of the first outer surface 544a of the device under test 530 depicted in FIG. 5 (advantageously taking into consideration the metal surface 550). Compared to the result depicted in FIG. 4, the far field shows less pronounced radiation oriented perpendicular to antenna elements of the first antenna array of the first outer surface 544a. Instead, the intensity of the far field is distributed more evenly around the device under test 540, with separate mainlobes in two directions which are different from a direction of a surface normal onto the first outer surface 544a. The result shows that a metalized surface in a close vicinity can affect the far field emitted by the device under test 540 and therefore reduce the accuracy and/or reproducibility of the test. For example, a metalized surface may reduce a spatial selectivity of a beamforming antenna array and/or change the direction of the mainlobe(s).

Therefore, an angle between the first outer surface 144a and the surface 112 of the carrier structure 110 (and optionally a spacing) such as described above can orient electrical fields emitted by and/or received at the first outer surface 114a (and optionally the second outer surface 144b) away from the carrier structure 110 and consequently improve the accuracy and/or reproducibility of the test.

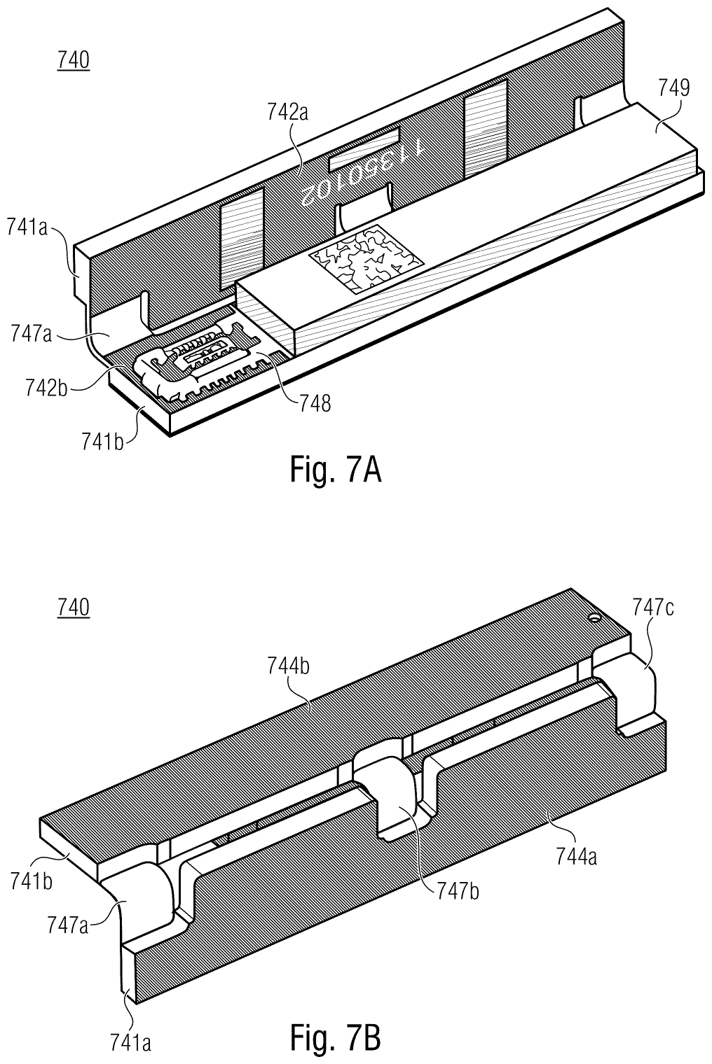

FIG. 7A shows a perspective view of an example of a device under test 740, which can take the place of the angled device under test 140. The device under test 740 comprises a first inner surface 742a and a second inner surface 742b. In the example shown in FIG. 7A, the device under test comprises a first plate 741a having the first inner surface 742a and a second plate 741b having the second inner surface 742b. The first and second plate 741a, b are mechanically (and optionally electrically) connected by flexible conducting structures such as three flexible printed circuits 747a, b, c. The first and second plate 741a, b may be movable (e.g., bendable) relative to each other (e.g., in order to facilitate manufacturing assembly in a system). However, the movability of the plates may, in some cases, facilitate a or coupling to the device-under-test socke). Alternatively, the first and second plate 741a, b may be arranged fixedly relative to each other.

The device under test 740 comprises an (array) connector 748 and a silicon die 749 (or any other antenna circuitry) on the second inner surface 742b. The silicon die 749 may be electrically contacted indirectly via the (array) connector 748 or directly via electrical contacts of the silicon die 749 itself (not shown in FIG. 7A). The device-under-test socket described herein is (e.g. by formation of respective antenna structures) configured to establish an electrical contact with the inner surface of the device under test 740 such as the (array) connector 748 on the second inner surface 742b.

FIG. 7B shows a different perspective view of the device under test 740 depicted in FIG. 7A. The device under test 740 comprises a first outer surface 744a (on the first plate 741a) and a second outer surface 744b (on the second plate 741b). The first and second outer surfaces 744a, b are configured (e.g. by formation of respective antenna structures) to emit and/or receive electromagnetic radiation. To this end, antenna elements (e.g., antenna arrays) may be arranged at least partly on the first and/or second surface 744a, b or be arranged at least partly within the first and/or second plate 741a, b. In the example shown in FIG. 7B, the first and second outer surface 744a, b are configured to emit and/or receive electromagnetic radiation. Alternatively, only the first or only the second outer surface 744a, b may be configured to emit and/or receive electromagnetic radiation.

As can be seen in FIG. 1, the second outer surface 144b forms a second angle 122 with the surface 112 of the carrier structure 110. The device-under-test socket 130 may be configured to position the angled device-under-test 130 such that the second outer surface 144b of the angled device-under-test 140 is tilted by a second angle 122 of at least 15 degrees with respect to the surface 112 of the carrier structure 110.

For example, the first angle 120 may be (at least essentially) 15°, 22.5°, 30°, 45°,60°, 67.5° or 75°. Similarly, the second angle 122 may be (at least essentially) 15°,22.5°, 30°, 45°, 60°, 67.5°, or 75°. The first and second inner surfaces 142a, b may form a right angle. In such a case, the first and second angle 120, 122 add up to 90 degrees. For example, the first and second angle 120 may be 15° and 75°, 22.5° and 67.5°, 30° and 60°, or 45° and 45° (i.e. an isosceles right triangle).

The test socket 130 may comprises (at least) two supporting surfaces 131a, b to support two inner surfaces 142a, b of the angled device under test 140. The two supporting surfaces 131a, b may be arranged at least essentially at a right angle (i.e.) 90°. At least one of the two supporting surfaces 131a, b may be formed recessed in the device-under-test socket 130. The two supporting surfaces 131a, b may be both tilted by at least 15 degrees with respect to the surface 112 (e.g. a main surface) of the carrier structure 110 (e.g. PCB test fixture or loadboard). For example the two supporting surfaces 131a, b may be arranged at least essentially at the same angle relative to each other as the two inner surfaces 142a, b (e.g., at 90 degrees). At least one of the two supporting surfaces 131a, b may be arranged at the first and second angle 120, 122 respectively (e.g., 15°, 22.5°, 30°, 45°, 60°,67.5° or 75° and vice versa).

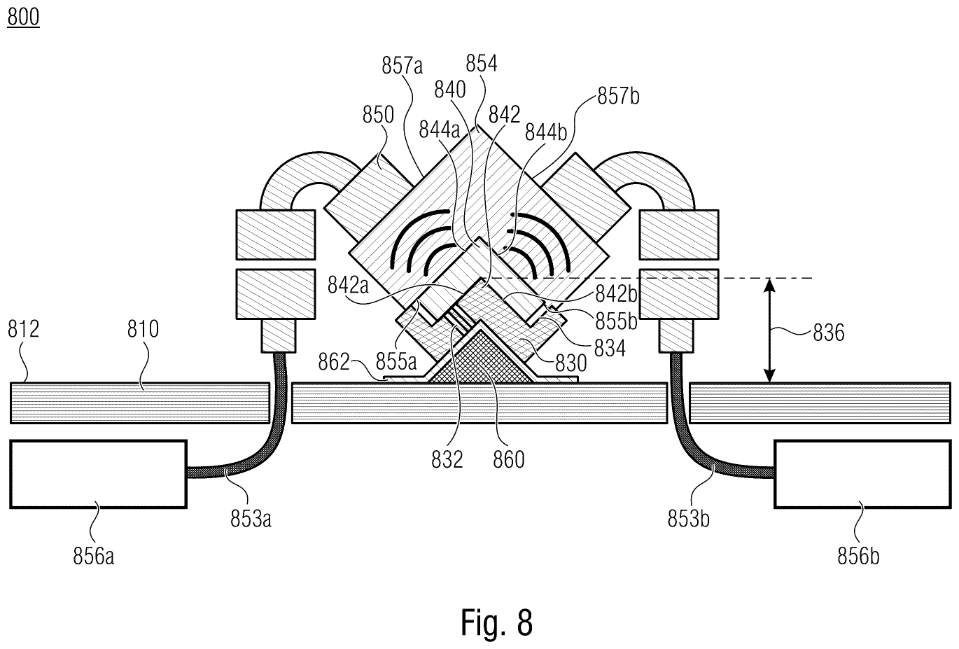

FIG. 8 shows a schematic cross section of an example of a test arrangement 800 for over-the-air testing an angled device under test 840.

The test arrangement 800 comprises a carrier structure 810 (which may be any carrier structure described herein) and a device-under-test socket 830 (which may be any device-under-test socket described herein).

In the example shown in FIG. 8, test arrangement 800 comprises a support structure 860 which is arranged on a surface 812 of the carrier structure 810 and which comprises a triangular cross-section (e.g. in a plane that is perpendicular to a plane in which the carrier structure 810 lies). The support structure 860 may be configured to carry the device-under-test socket 830 (e.g. directly or with one or more layers in between). The support structure 860 may comprise attachment features configured to be attach the support structure 860 to the carrier structure 110. The attachment features may comprise at least one of an opening (e.g., configured to receive a screw), a screw, a magnet, and a pin. The support structure 860 may consist of or comprise a dielectric material and/or metal. The support structure 860 may comprise (e.g., inside) electrical connections, e.g., for establishing an electrical connection between the device-under-test socket 830 and the carrier structure 810 (and/or any other device).

As shown in FIG. 8, the test arrangement 800 may comprise a flexible or membrane or elastomeric planar conductor structure 862 (e.g. a flexible or elastomeric printed circuit board) which is arranged to make a connection between the surface 812 of the carrier structure 810 and a surface of the device-under-test socket 830 (e.g., for routing electrical signals to the device-under-test socket 830) which is tilted with respect to the surface 812 of the carrier structure 810. In the example shown in FIG. 8, the planar conductor structure 862 covers two surfaces of the support structure 860. Alternatively, the planar conductor structure 862 may cover only (at least a part) of one surface of the support structure 860. Further alternatively, the planar conductor structure 862 may be arranged between the support structure 860 and the carrier structure 810.

As shown in FIG. 8, the flexible or Membrane or elastomeric planar conductor structure 862 may be electrically coupled to a surface of the carrier structure 810 and comprise at least one bent to align with a lower surface of the device under test socket 830. The flexible or membrane or elastomeric planar conductor structure 862 may extend (at least partly) on a surface of the support structure 860. The support structure 860 may be arranged on a surface 812 of the carrier structure 810 and may comprise a triangular cross-section (e.g. in a plane that is perpendicular to a plane in which the carrier structure lies). The cross-section may have the shape of a (e.g., right) isosceles triangle.

The support structure 860 may be configured to carry the device under test socket 830 (e.g. directly or with one or more layers in between). To this end, the support structure 860 may (directly or indirectly) attached to the device under test socket 830 (e.g., for easier handling) or removable from the device under test socket 830 (e.g., for combination of different device-under-test sockets). The flexible or membrane or elastomeric planar conductor structure 862 may be partly arranged between the support structure 860 and the device under test socket 830. Further layers (e.g., at least one of a shock absorbing layer and a height adjusting layer) may be arranged between the planar conductor structure 862 and at least one of the device under test socket 830 and the support structure 860.

In the example shown in FIG. 8, the device under test socket 830 comprises one or more coaxial pogo pins 832, in order to establish an electrical connection with the angled device under test 830.

The coaxial pogo pins 832 may, for example, extend from a lower surface of the device under test socket 830 which may be in contact with the carrier structure 810 (e.g., with the PCB test fixture or with the load board) or with the support structure 860 or with the flexible or membrane or elastomeric planar conductor structure 862, to an upper surface of the device under test socket 830, which is in contact with the inner surface 842 (e.g., an first and/or second inner surface) of the angled device under test 840.

A first end of the coaxial pogo pin 832 may be in contact with a pad on the carrier structure 810 (e.g., on the PCB test fixture or on the load board) or on the support structure 860 or on the flexible or membrane or elastomeric planar conductor structure 862. A second end of the coaxial pogo pin may be in contact with a pad on the angled device under test 840 or with a connector of the angled device under test 840. One or both ends of the coaxial pogo pin 832 may be retractable. For example, the first end of the coaxial pin 832 may be retractable upon the device-under-test 840 being inserted into the device-under-test socket 830. Alternatively or additionally, the second of the coaxial pin 832 may be retractable upon the device-under-test socket 830 being arranged onto the support structure 860 and/or the flexible or membrane or elastomeric planar conductor structure 862.

The test arrangement 800 may comprise one or more antenna structures. For example, the test arrangement 800 may comprise a first antenna or antenna structure 850 (e.g. a single aperture antenna (e.g. dual linear polarized or circular polarized)) configured to receive a signal radiated from the first outer surface 844a of the angled device under test 840 and/or configured to emit a signal to be received at the first outer surface 844a of the angled device 840.

The first antenna or antenna structure 850 may comprise an aperture, e.g., fed by a waveguide.

An aperture of the first antenna or antenna structure 850 may be arranged at a distance from the first outer surface 844a of the angled device under test 840, such that a surface normal of the first outer surface of the angled device under test extends through the aperture of the first antenna or antenna structure (at least when the second antenna or antenna structure is placed at an operation position).

The distance from the first outer surface 844a may be realized with a pusher 854 comprising a low permittivity material or an electromagnetic transparent material arranged in between the first antenna or antenna structure 850 and the first outer surface 844a. The pusher 854 may be configured to push the device under test 840 into the device-under-test socket 830. To this end, the pusher 854 may comprise attachment elements configured to attach the pusher 854 (directly or indirectly) with the carrier structure 810.

An antenna aperture of the first antenna or antenna structure 850 may be tilted with respect to the carrier structure 810 (e.g. with respect to a surface or main surface 812 of the carrier structure 810). The antenna aperture may be tilted by at least essentially the first angle between the first outer surface 844a and the surface 812 of the carrier structure 810. The antenna aperture of the first antenna or antenna structure 850 may be arranged at least essentially parallel to the first outer surface 844a. In the example shown in FIG. 8, the antenna aperture of the first antenna or antenna structure 850 and the first outer surface 844a are tilted 45° relative to the surface 812 of the carrier structure 810. Alternatively, the antenna aperture of the first antenna or antenna structure 850 and the first outer surface 844a may be tilted at different angles.

The first antenna or antenna structure 850 may be mounted to have a fixed position with respect to the device under test socket 830. To this end, the first antenna or antenna structure 850 and the device under test socket 830 may both have a fixed position with respect to the carrier structure 810. Alternatively, the first antenna or antenna structure 850 may have an adjustable position with respect to the device under test socket 830.

The first antenna or antenna structure 850 may be mechanically coupled to (e.g. attached to) an arm of a handler (e.g., pusher 854), such that the first antenna or antenna structure 850 is moveable.

The arm of the handler may be configured to insert the angled device under test 840 into the device under test socket 830, and/or to push the device under test 840 into the device under test socket 830.

The first antenna or antenna structure 850 may be configured to be connected with a first signal source and/or with a signal receiver 856a via a blind-mating microwave connection (e.g. via a blind mating waveguide connection) when the handler has placed the first antenna or antenna structure 850 in an operating position (or, equivalently, when the handler has inserted the angled device under test 840 into the device under test socket 830, or when the handler pushes the device under test 840 into the device under test socket 830).

In the example shown in FIG. 8, the first antenna or antenna structure 850 comprises (or is connected to) a first coaxial cable 853a connected (or connectable) with a first signal source and/or with a signal receiver 856a. However, any other form of electrical signal transmission may be used instead. Alternatively or additionally, the first antenna or antenna structure 850 may be connected to any other device. The first coaxial cable 853a may extend through an opening. Alternatively, the coaxial cable 853a may extend through no opening (e.g., extend at the same side as the device-under-test socket 840 and/or first antenna or antenna structure 850).

As can be seen in FIG. 8, the test arrangement 800 may comprise a second antenna or antenna structure 952 (e.g. a single aperture antenna (e.g. dual linear polarized or circular polarized)) configured to receive a signal radiated from the second outer surface 844b of the angled device under test 840 and/or to emit a signal to be received at the second outer surface 844 b of the angled device under test 840 (at least when the second antenna or antenna structure 852 is placed at an operation position or, equivalently, when the handler has inserted the angled device under test 840 into the test socket 830, or when the handler pushes the device under test 840 into the test socket 830). The second antenna or antenna structure 852 may comprise an aperture, e.g., fed by a waveguide.

An aperture of the second antenna or antenna structure 852 may be arranged at a distance from the second outer surface 844b of the angled device under test 840 (e.g. with a pusher 854 comprising a low permittivity material or an electromagnetic transparent material in between the second antenna or antenna structure 852 and the second outer surface 844b), such that a surface normal of the second outer surface 844b of the angled device under test 840 extends through the aperture of the second antenna or antenna structure 852 (at least when the second antenna or antenna structure 852 is placed at an operation position or, equivalently, when the handler has inserted the angled device under test 840 into the test socket 830, or when the handler pushes the device under test 840 into the test socket 830).

The distance from the second outer surface 844b may be realized with the pusher 854. The pusher 854 may comprise a low permittivity material or an electromagnetic transparent material arranged in between the second antenna or antenna structure 852 and the second outer surface 844b. In the example shown in FIG. 8, the test arrangement 800 comprises a common pusher 854 for the first and second antenna or antenna structure 850, 852 (and for the first and second outer surfaces 844a, b). Alternatively, a separate pusher may be provided for each one of the first and second antenna structure 850, 852 (and/or the respective first and second outer surfaces 844a, b).

An antenna aperture of the second antenna or antenna structure 852 may be tilted with respect to the carrier structure 810 (e.g. with respect to a surface or main surface of the carrier structure). The antenna aperture of the second antenna or antenna structure 852 may be tilted by at least essentially the second angle between the second outer surface 844b and the surface 812 of the carrier structure 810. The antenna aperture of the second antenna or antenna structure 852 may be arranged at least essentially parallel to the second outer surface 844b. In the example shown in FIG. 8, the antenna aperture of the second antenna or antenna structure 852 and the second outer surface 844b are tilted 45° relative to the surface 812 of the carrier structure 810. Alternatively, the antenna aperture of the second antenna or antenna structure 852 and the second outer surface 844b may be tilted at different angles.

The second antenna or antenna structure 852 may be mounted to have a fixed position with respect to the device under test socket 830. To this end, the second antenna or antenna structure 852 and the device under test socket 830 may both have a fixed position with respect to the carrier structure 810. Alternatively, the second antenna or antenna structure 852 may have an adjustable position with respect to the device under test socket 830.

The second antenna or antenna structure 852 may be mechanically coupled (e.g. attached) to an arm of a handler (e.g., in form of the pusher 854), such that the second antenna or antenna structure is moveable. The handler may be configured to insert the angled device under test 840 into the device under test socket 830. The arm of the handler may be configured to insert the angled device under test 840 into the device under test socket 830, and/or to push the device under test 840 into the device under test socket 830.

The first antenna or antenna structure 850 and/or the second antenna or antenna structure 852 may be part of a pusher for pushing the angled device under test 840 into the device under test socket 830. The first antenna or antenna structure 850 and/or the second antenna or antenna structure 852 may be configured to be moveable together with a pusher for pushing the angled device 840 under test into the device under test socket. For example, the pusher may be arranged such that the pusher, or a part of the pusher, is in between the first antenna or antenna structure 850 and the first outer surface 844a of the angled device under test 840 when the device under test 840 in inserted into the device under test socket 830. For example, the pusher may be arranged such that the pusher, or a part of the pusher, is in between the second antenna or antenna structure 852 and the second outer surface 844b of the angled device under test 840 when the device under test 840 in inserted into the device under test socket 830. The pusher may comprise one or more apertures connected with a waveguide configured to transmit electromagnetic waves between the aperture and at least one of the first and second antenna or antenna structure 850, 852.

The second antenna or antenna structure 852 may be configured to be connected with a second signal source and/or with a signal receiver 856b via a blind-mating microwave connection (e.g. via a blind mating waveguide connection) when the handler has placed the second antenna or antenna structure 852 in an operating position (or, equivalently, when the handler has inserted the angled device under test into the test socket, or when the handler pushes the device under test into the test socket).

It is noted that the test arrangement 800 shown in FIG. 8 has two separate signal sources and/or signal receivers 856a, b. However, the test arrangement 800 may have a common (e.g., single) signal source and/or signal receiver, which may be connected to the first and second antenna or antenna structure 950, 952 by separate or common electrical connections (such as a coaxial cable).

The pusher 854 may be configured such that a first pushing surface 855a is parallel to the first outer surface 844a of the angled device under test 840 when the pusher is in a pushing position and such that a second pushing surface 855b is parallel to the second outer surface 844b of the angled device under test 840 when the pusher is in the pushing position. In the example shown in FIG. 8, the first and second outer surfaces 844a, b are arranged at a right angle (i.e.) 90° relative to each other and the first and second pushing surface 855a, b of the pusher 852 are also arranged at a right angle relative to each other. At least one of the first and second pushing surfaces 855a, b may be formed in a recess of the pusher 854, e.g., in order to facilitate alignment between the pusher 854 and the device under test 840. The pusher 854 may have further recesses configured to receive at least a portion of the device-under-test socket 830 when the pusher 854 pushes the device under test 840 into the device-under-test socket 830.

The pusher 854 may be configured such that the first pushing surface 855a of the pusher 854 is tilted with respect to the carrier structure 810 when the pusher 854 is in the pushing position. The pusher 854 is configured such that a second pushing surface 855b of the pusher 854 is tilted with respect to the carrier structure 810 when the pusher 854 is in the pushing position.

In the example shown in FIG. 8, apertures of the first and second antenna or antenna structure 850, 852 are arranged parallel to the first and second outer surfaces 844a, b of the device under test 840 when coupled to the device-under-test socket 830. As a result, the pusher 854 may a first outer pusher surface 857a that is arranged parallel to the first pushing surface 855a and a second outer pusher surface 857b that is arranged parallel to the second pushing surface 855b.

However, the apertures of the first and second antenna or antenna structure 850, 852 may be arranged at a different angle than the outer surfaces 844a, b. For example, the first and second outer surfaces 844a, b may be arranged at an angle of 40° and 50° relative to the surface 812 of the carrier structure 810 respectively and the apertures of the first and second antenna or antenna structure 850, 852 may be arranged at 45° relative to the surface 812 of the carrier structure 810. The pusher 854 may be configured to compensate an angular mismatch between the apertures of the first and second antenna or antenna structure 850, 852 and the first and second outer surfaces 844a, b. For example, the first and second outer pusher surfaces 857a may be arranged to be tilted by 5° relative to the first and second pushing surfaces 855a, b. Alternatively or additionally, at least one of the first and second antenna or antenna structures 850, 852 may be configured to be adjustable in at least one of position and orientation.

The device under test socket 830 may comprises an angled recess or an angled exemption 834, configured to support and/or align the angled device under test 840. In the example shown in FIG. 8, the angled recess or angled exemption 834 has a cross-section in the shape of an L, e.g., in form of two plates arranged at a right angle. The angled recess or angled exemption 834 may have one or two lateral sidewalls (e.g., parallel to the cross-section of the angled recess or angled exemption 834), e.g., in order to reduce lateral movement of the device under test 840 inside the device-under-test socket 830. The angled recess or angled exemption 834 may be bordered by a step. In the example shown in FIG. 8, the step has at least essentially the same height as a distance between the first inner surface and the first outer surface 844a of the device under test 840. As a result, the first outer surface 844 is arranged flush with the step of the device-under-test socket 830. Alternatively, the step may have a larger height (e.g., in order to provide support for the pusher 846) or a smaller height (e.g., in order to not limit pressure applicable by the pusher 846 onto the device under test 840. It is noted that in FIG. 8, the first and second pushing surfaces 855a, b are dimensioned larger than the first and second outer surface 844a, b. Alternatively, the first and second pushing surfaces 855a, b may be dimensioned at least essentially identical or smaller than the first and second outer surface 844a, b.

The device under test 840 may comprise a first inner surface 842a of the angled device 840, which is opposite to the first outer surface 844a of the angled device under test 840. The device under test 840 may comprise a second inner surface 842b of the angled device 840, which is opposite to the second outer surface 844b of the angled device under test 840. The device-under-test socket 830 may be arranged such that the first inner surface 842a and/or the second inner surface 842b of the angled device under test 840 is spaced from the carrier structure 810 (e.g. loadboard) by at least 10 mm, or by at least 30 mm, or by at least 45 mm or by at least 2 wavelengths or by at least 3 wavelengths or by at least by 4 wavelengths (e.g. free-space wavelengths, or wavelengths in a medium between the first outer surface of the angled device under test and the carrier structure) at a lowest frequency of operation of the angled device under test.

For example, the lowest frequency of operation may be a lowest frequency of operation of an Antenna-in-Package (AiP) module that makes up the device under test 840 or that is included in the device under test 840.

The device-under-test socket 830 may be arranged such that, advantageously, an edge of the first and/or second outer surface 844a, b is spaced from the loadboard by at least 10 mm, or by at least 20 mm or by at least 2 wavelengths or by at least 3 wave-lengths or by at least by 4 wavelengths, e.g. free-space wavelengths, or wavelengths in a medium between the first and/or second outer surface 844a, b of the angled device under test 840 and the carrier structure 810, at a lowest frequency of operation of the angled device under test, e.g. at a lowest frequency of operation of an Antenna-in-Package (AiP) module that makes up the device under test or that is included in the device under test.

The device under test socket 830 may comprise a maximum socket height 836 (e.g., over the surface 812 of the carrier structure 810) of at least 10 mm, or of at least 30 mm, or of at least 45 mm, or of at least 2 wavelengths or of at least 3 wavelengths or of at least by 4 wavelengths (e.g. free-space wavelengths, or wavelengths in a medium between an edge of two supporting surfaces of the of the device-under-test socket 830 and the carrier structure 810) at a lowest frequency of operation of the angled device under test (e.g. at a lowest frequency of operation of an Antenna-in-Package (AiP) module that makes up the device under test or that is included in the device under test). The maximum socket height 836 may be a height over the carrier structure 810 where an inner edge of the angled device under test 840 is located when the angled device under test 840 is placed in the device under test socket 830. The maximum socket height 836 may be a height over the carrier structure 810 where an edge between two supporting surfaces of the device under test socket 830 is located.

The first antenna or antenna structure 850 and the second antenna or antenna structure 852 may be arranged such that the angled device under test 840 can be inserted into the device under test socket 830 in a direction which is perpendicular to a surface 812 (e.g. a main surface) of the carrier structure 810 without moving the first antenna and the second antenna 850, 852. Alternatively or additionally, the first antenna or antenna structure 850 and the second antenna or antenna structure 852 may be arranged such that the angled device under test 840 can be removed from the device under test socket 830 in a direction which is perpendicular to a surface 812 (e.g. a main surface) of the carrier structure 810 without moving the first antenna or antenna structure 850 and the second antenna or antenna structure 852. The pusher 854 may be dimensioned such that the pusher 854 abuts against the device under test 840 and the first and second antenna or antenna structure 850, 852 when the device under test 840, the pusher 854, and the first and second antenna or antenna structure 850, 852 are in an operation position.

A spacing (e.g., in a direction parallel to the surface 812 of the carrier structure 810) between the first antenna or antenna structure 850 and the second antenna or antenna structure 852 may be chosen such that the angled device under test can be straightly (e.g. in a straight line) moved through the spacing in a direction which is perpendicular to a surface (e.g. a main surface) of the carrier structure. The spacing may be chosen such that the antenna device 840 may be moved through spacing at least essentially without rotation or with a rotation such that the first or second outer (or inner) surface 844a, b is oriented at least essentially parallel to the surface 812 of the carrier structure 810. The spacing may be wider than 5, 10, or 20% of a width of the device under test 840 without or with rotation.

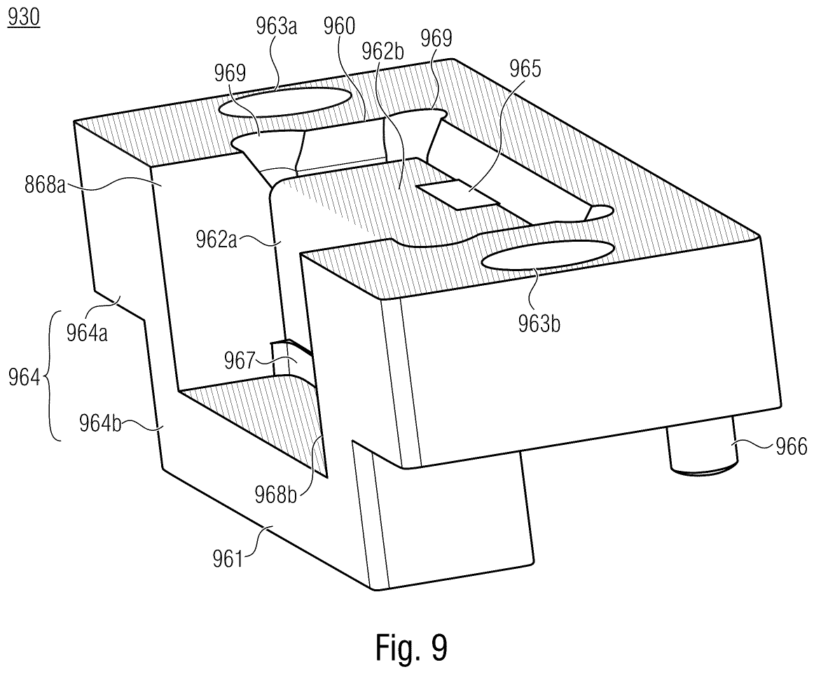

FIG. 9 shows a perspective view of an example of a device-under-test socket 930 which may, for example, be used in any of the embodiments disclosed herein.

The device-under-test socket 930 may be configured to receive any device under test described herein and be part of any test arrangement described herein. The device-under-test socket 930 may be configured to be coupled with (e.g., inserted into) any support structure described herein (e.g., support structure 860), wherein, optionally, further components such as the flexible or membrane or elastomeric planar conductor structure 862 may be arranged at least partly between the device-under-test socket 930 and the support structure.

The device-under-test socket 930 comprises an angled recess or an angled exemption 960, configured to support and/or align the angled device under test. The angled recess or the angled exemption 960 comprises a first abutment surface 962a configured to abut against the first inner surface of the device under test (e.g., first inner surfaces 142a, 242a, or 742a) and a second abutment surface 962b configured to abut against the second inner surface of the device under test (e.g., second inner surface 142b, 242b, or 742b). The first abutment surface 862a and the second abutment surface 962b may be arranged at an abutment surface angle, wherein a sum of the abutment surface angle (e.g. 270 degree) and of the angle between the first and second inner surface of the device under test (e.g. 90 degree) is at least essentially 360 degrees. For example, if the first and second inner surface of the device under test may be arranged at an angle of 90 degrees, the abutment surface angle may be 270 degrees (with the sum of 90 degrees and 270 degrees being 360 degrees).

Any surface of the device-under-test socket 930 may be configured to establish an electrical contact with the inner surface of the device under test. For example, the first and/or second abutment surface 962a, b may be configured to establish an electrical contact with the inner surface of the device under test, and/or to provide a ground plane for an antenna structure of the device under test. To this end, the first and/or second abutment surface 962a, b may comprise or may be formed of an electrically conducting material (e.g., at least one of gold, cupper, iron, and nickel). Alternatively, the first and/or second abutment surface may comprise, or may be formed of, a dielectric (non-conducting) material (e.g. a wear-resistant material). Optionally, the first and/or second abutment surface 962a, b may comprise one or more (local) socket connectors 965 (or other contacting structures for contacting the device under test, like conductive pads, pogo pins, spring-loaded contacts, or the like). The socket connector 965 is arranged such that when the device under test is arranged in the device-under-test socket 960, the connector 965 establishes an electrical connection with the inner surface of the device under test or a connector thereof (e.g., array connectors 248, 748).

The device-under-test socket 930 comprises a support body 964 comprising a main socket structure 964a and a leg socket structure 964b. The main socket structure 964a and the leg socket structure 964b both have a rectangular cuboid outer shape (optionally with rounded edges), wherein at least two edges of the leg socket structure 964b are smaller (shorter) than two edges (e.g. corresponding edges) of the main socket structure 964a. The main socket structure 964a and the leg socket structure 964b may, for example, have the same height. A side surface of the leg socket structure 964b is arranged flush with a side surface of the main socket structure 964a, and three other side surfaces of the leg socket structure 964b are recessed relative to three other (corresponding) side surfaces of the main socket structure 964a. The leg socket structure 964b may therefore, for example, be received by an opening in the carrier structure (or an extender structure coupled to the carrier structure) such that, for example, lateral movement of the device-under-test socket 930 is limited by side surfaces of the leg socket structure 964b. However, the device-under-test socket may also be attached on top of an extender structure, wherein the main socket structure 964a may be arranged on a top surface of the extender structure, and wherein the leg socket structure 964b may be adjacent to a side wall of the extender structure.

The device-under-test socket 930 may further or alternatively comprise one or more protrusions 966 extending from the support body 964 (e.g., from the main socket structure 964a) in a direction towards the carrier structure. The protrusion 966 may be or comprise a shaft (e.g., with a cylinder shape). The protrusion 966 may be received by a recess of the carrier structure. Alternatively or additionally, the device-under-test socket 930 may comprise one or more through holes configured to receive an attachment element such as a pin or screw.

In the example shown in FIG. 9, the angled recess or the angled exemption 960 extends into the main socket structure 964a and a leg socket structure 964b.

Alternatively, the angled recess or the angled exemption 960 may only extend into the main socket structure 964a.

The angled recess or the angled exemption 960 may have a respective sidewall 968a, b at both of its ends (only one of which is directly visible in FIG. 9). The sidewalls 968a, b face each other and are arranged at least essentially parallel to each other (disregarding an optional tapering). In the example shown in FIG. 9, the sidewalls 968a, b are oriented perpendicular or at least approximately perpendicular relative to the first and second abutment surfaces 962a, b. The sidewalls 968a, b may restrict lateral movement of the device under test within the angled recess or the angled exemption 960, while still allowing for a smooth and well-guided insertion of the device under test into the angled recess or the angled exemption 960 and also allowing for a smooth extraction of the device under test. Alternatively, the angled recess or the angled exemption 960 comprise only one sidewall or no sidewall, e.g., in order to increase flexibility in regards to positioning.

The angled recess or the angled exemption 960 may comprise at least one tapering, e.g., such that a cross section (e.g., parallel to the first or second abutment surface 962a, b) decreases in a direction from outside towards the first or second abutment surface 962b. In the example shown in FIG. 9, the angled recess or the angled exemption 960 comprises a first and a second tapering. According to a first tapering, a distance between the sidewalls 968a, b decreases towards the first abutment surface 962a. According to a second tapering, three sidewalls of the main socket structure 964a that are surrounding the second abutment surface 962b have a cross section that decreases towards the second abutment surface 962b. The tapering may have a self-centering function and facilitate inserting the device under test into the angled recess or the angled exemption 960.

The device-under-test socket 930 may have adjacent openings 969 that intersect the angled recess or the angled exemption 960. In the example shown in FIG. 9, the device-under-test socket 930 comprises four adjacent openings 969 that are arranged next to corners of the second abutment surface 962b. Alternatively, the device-under-test socket 930 may comprise any other number of adjacent openings 969 at any other location that is located adjacent to the second abutment surface 962b (and/or the first abutment surface 962a). At least one of the adjacent openings 969 may be configured to receive a screw with a screw head that is configured to abut against the outer first or second surface of the device under test when the device under test is inserted into the angled exemption 960 and the screwed is screwed in. The adjacent openings 969 therefore may allow attaching the device under test in the device-under-test socket 930. Alternatively or additionally, at least one of the adjacent openings 969 may be configured to receive a grabbing element (e.g., a clamping device or a finger of a user) such that the grabbing element can touch the device under test from the side (e.g., in order to insert the device under test into the device-under-test socket and/or retrieve the device under test from the device-under-test socket 930). For example, the adjacent openings may be adapted to prevent the device under test from canting, e.g. when the device under test is inserted into the socket 930. However, the adjacent openings may also be helpful to retrieve the device under test from the socket 930.

The angled recess or the angled exemption 960 may comprise additional recesses or elevations, e.g., in order to conform to a shape of the device under test. For example, the angled recess or the angled exemption 960 shown in FIG. 9 comprises a step 967 in the first abutment surface 962a. The step 967 may, for example, accommodate to a structural feature of the first inner surface or provide a support surface for the device under test such as to form a space below (e.g., for grabbing the device under test).

The device-under-test socket 930 may comprise a blind mating interface. In the example shown in FIG. 9, the main socket structure 964a comprises two (e.g., blind) mating recesses 963a,b. Alternatively, the main socket structure 964a may comprise any other amount of mating recesses. The mating recesses 963a, b are configured to receive (e.g., blind) mating protrusions of a pusher or handler (e.g., handler 754). Alternatively or additionally the main socket structure 964a may comprise one or more (e.g., blind) mating protrusions, for example, configured to be received by a (e.g., blind) mating recess of the pusher or handler (e.g., handler 754).

To conclude, the socket 930 may receive an angled device under test and may establish an electrical contact with the angled device under test. The device under test may be positioned (aligned) within the angled recess or angled exemption 960, such that an over-the-air test of the device under test is possible using antenna structures or antennas on both outer surfaces of the angled device under test. The device under test is well aligned in the socket, while distortions of radiation characteristics of the antennas or antenna structures of the device under test by the socket can be kept reasonably small. The socket can be easily attached to a carrier structure and can be used in any of the embodiments disclosed herein.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A test arrangement for over-the-air testing an angled device under test, the test arrangement comprising:
a carrier structure, and
a device-under-test socket;
wherein the device-under-test socket is coupled to the carrier structure,
wherein the device-under-test socket is configured to establish an electrical contact with an inner surface of the angled device under test or with a connector which is arranged on the inner surface of the angled device under test, and
wherein the device-under-test socket is configured to position the angled device-under-test
such that a first outer surface of the angled device-under-test is tilted by at least 15 degrees with respect to a surface of the carrier structure.

2. The test arrangement according to claim 1,
wherein the device-under-test socket is configured to position the angled device-under-test
such that a second outer surface of the angled device-under-test is tilted by at least 15 degrees with respect to the surface of the carrier structure.

3. The test arrangement according to claim 1,
wherein the test socket comprises two supporting surfaces to support two inner surfaces of the angled device under test,
wherein the two supporting surfaces are both tilted by at least 15 degrees with respect to the surface of the carrier structure.

4. The test arrangement according to claim 1, further comprising:
a support structure;
wherein the support structure is arranged on the surface of the carrier structure and comprises a triangular cross-section;
wherein the support structure is configured to carry the device under test socket.

5. Test arrangement according to claim 4, further comprising:
a flexible conductor structure or a membrane conductor structure or an elastomeric planar conductor structure;
wherein the flexible conductor structure or the membrane conductor structure or the elastomeric planar conductor structure is arranged to make a connection between the surface of the carrier structure and a surface of the device under test socket which is tilted with respect to the surface of the carrier structure;
wherein the flexible conductor structure or the membrane conductor structure or the elastomeric planar conductor structure is electrically coupled to the surface of the carrier structure and comprises at least one bent to align with a lower surface of the device under test socket;
wherein the flexible conductor structure or the membrane conductor structure or the elastomeric planar conductor structure extends on a surface of the support structure, and
wherein the flexible conductor structure or the membrane conductor structure or the elastomeric planar conductor structure is partly arranged between the support structure and the device under test socket.

6. The test arrangement according to claim 1, further comprising:
a first antenna structure;
wherein the first antenna structure is configured to receive a signal radiated from the first outer surface of the angled device under test and/or configured to emit a signal to be received at the first outer surface of the angled device;
wherein an antenna aperture of the first antenna structure is arranged at a distance from the first outer surface of the angled device under test, such that a surface normal of the first outer surface of the angled device under test extends through the antenna aperture of the first antenna structure; and
wherein the antenna aperture of the first antenna structure is tilted with respect to the carrier structure.

7. The test arrangement according to claim 6,
wherein the antenna aperture of the first antenna structure is parallel to the first outer surface of the angled device under test.

8. The test arrangement according to claim 6, further comprising:
a handler;
wherein the first antenna structure is mechanically coupled to an arm of the handler, such that the first antenna structure is moveable.

9. The test arrangement according to claim 8, further comprising:
a signal source or a signal receiver;
wherein the first antenna structure is configured to be connected with the signal source or with the signal receiver via a blind-mating microwave connection when the handler has placed the first antenna structure in an operating position.

10. The test arrangement according to claim 2, further comprising:
a second antenna structure;
wherein the second antenna structure is configured to receive a signal radiated from the second outer surface of the angled device under test and/or to emit a signal to be received at the second outer surface of the angled device under test;
wherein an antenna aperture of the second antenna structure is arranged at a distance from the second outer surface of the angled device under test, such that a surface normal of the second outer surface of the angled device under test extends through the antenna aperture of the second antenna structure; and
wherein the antenna aperture of the second antenna structure is tilted with respect to the carrier structure.

11. The test arrangement according to claim 10,
wherein the antenna aperture of the second antenna structure is parallel to the second outer surface of the angled device under test.

12. The test arrangement according to claim 10, further comprising:
a handler;
wherein the second antenna structure is mechanically coupled to an arm of the handler, such that the second antenna structure is moveable.

13. The test arrangement according to claim 6, further comprising:
a pusher;
wherein the pusher is configured to push the angled device under test into the device under test socket;
wherein the first antenna structure is part of the pusher, or
wherein the first antenna structure is configured to be moveable together with the pusher.

14. Test arrangement according to claim 2, further comprising:
a pusher;
wherein the pusher is configured to push the angled device under test into the test socket;
wherein the pusher is configured such that a first pushing surface of the pusher is parallel to the first outer surface of the angled device under test when the pusher is in a pushing position, and
wherein the pusher is configured such that a second pushing surface of the pusher is parallel to the second outer surface of the angled device under test when the pusher is in the pushing position.

15. The test arrangement according to claim 2, further comprising:
a pusher;
wherein the pusher is configured to push the angled device under test into the test socket,
wherein the pusher is configured such that a first pushing surface of the pusher is tilted with respect to the carrier structure when the pusher is in the pushing position, and
wherein the pusher is configured such that a second pushing surface of the pusher is tilted with respect to the carrier structure when the pusher is in the pushing position.

16. The test arrangement according to claim 2,
wherein the device under test socket is arranged such that a second inner surface of the angled device under test, which is opposite to the second outer surface of the angled device under test, is spaced from the carrier structure by at least 10 mm.

17. The test arrangement according to claim 1,
wherein the device under test socket comprises a maximum socket height of at least 10 mm.

18. The test arrangement according to claim 6, further comprising:
a second antenna structure;
wherein the device-under-test socket is configured to position the angled device-under-test
such that a second outer surface of the angled device-under-test is tilted by at least 15 degrees with respect to the surface of the carrier structure;
wherein the second antenna structure is configured to receive a signal radiated from the second outer surface of the angled device under test and/or to emit a signal to be received at the second outer surface of the angled device under test;
wherein an antenna aperture of the second antenna structure is arranged at a distance from the second outer surface of the angled device under test, such that a surface normal of the second outer surface of the angled device under test extends through the antenna aperture of the second antenna structure;
wherein the antenna aperture of the second antenna structure is tilted with respect to the carrier structure;
wherein the first antenna structure and the second antenna structure are arranged such that the angled device under test can be inserted into the device under test socket in a direction which is perpendicular to the surface of the carrier structure without moving the first antenna structure and the second antenna structure, and
wherein the first antenna structure and the second antenna structure are arranged such that the angled device under test can be removed from the device under test socket in a direction which is perpendicular to the surface of the carrier structure without moving the first antenna structure and the second antenna structure.

19. The test arrangement according to claim 18,
wherein a spacing between the first antenna structure and the second antenna structure is chosen such that the angled device under test can be straightly moved through the spacing in a direction which is perpendicular to the surface of the carrier structure.

20. A test arrangement for over-the-air testing an angled device under test, the test arrangement comprising:
a carrier structure, and
a device-under-test socket;
wherein the device-under-test socket is coupled to the carrier structure,
wherein the device-under-test socket is configured to establish an electrical contact with an inner surface of the angled device under test or with a connector which is arranged on the inner surface of the angled device under test, and
wherein the device-under-test socket is configured to position the angled device-under-test
such that a first outer surface of the angled device-under-test is tilted by at least 15 degrees with respect to a surface of the carrier structure, and
such that a second outer surface of the angled device-under-test is tilted by at least 15 degrees with respect to the surface of the carrier structure.
